(19) United States
(12) Patent Application Publication
(10) Pub. No.: US 2024/0075499 A1
(43) Pub. Date: Mar. 7, 2024

(54) MEMS ULTRASONIC TRANSDUCER DEVICE AND MANUFACTURING PROCESS THEREOF

(71) Applicant: STMICROELECTRONICS S.r.l., Agrate Brianza (IT)

(72) Inventor: Francesco FONCELLINO, Casagiove (IT)

(73) Assignee: STMICROELECTRONICS S.r.l., Agrate Brianza (IT)

(21) Appl. No.: 18/455,540

(22) Filed: Aug. 24, 2023

(30) Foreign Application Priority Data
Sep. 5, 2022 (IT) 102022000018153

(51) Int. Cl. B06B 1/02; G01S 7/534

(52) U.S. Cl. CPC B06B 1/0292; G01S 7/534

(57) ABSTRACT

MEMS ultrasonic transducer, MUT, device, comprising a semiconductor body with a first and a second main face, including: a modulation cavity extending into the semiconductor body from the second main face; a membrane body suspended on the modulation cavity and comprising a transduction membrane body and a modulation membrane body; a piezoelectric modulation structure on the modulation membrane body; a transduction cavity extending into the membrane body, the transduction membrane body being suspended on the transduction cavity; and a piezoelectric transduction structure on the transduction membrane body. The modulation membrane body has a first thickness and the transduction membrane body has a second thickness smaller than the first thickness. In use, the modulation membrane vibrates at a first frequency and the transduction membrane vibrates at a second frequency higher than the first frequency, to emit and/or receive acoustic waves at a frequency dependent on the first and the second frequencies.

### BACKGROUND

### Technical Field

The present disclosure relates to a MEMS ultrasonic transducer, MUT, device. Furthermore, it relates to a manufacturing process and a control method of the MUT device. In particular, the MUT device is frequency-modulable and, in use, emits and/or receives acoustic waves with a frequency depending on the emission direction.

### Description of the Related Art

As known, proximity sensors may be provided by time-of-flight sensors. In particular, the time-of-flight sensors may be ultrasonic transducers, for example made using MEMS (“Micro Electro-Mechanical Systems”) technology. A known class of MEMS ultrasonic transducers uses piezoelectric technology for the emission and detection of acoustic waves, as better described below.

In use, ultrasonic transducers are immersed in a fluid (generally with low density, e.g., air) and are controlled to generate and detect ultrasonic acoustic waves (e.g., with a frequency comprised between 20 kHz and 500 MHz, for example equal to 2 or 3 MHz). In detail, as exemplarily shown in FIG. 1, the ultrasonic transducer T generates an ultrasonic wave (or emitted wave, indicated in FIG. 1 with the reference Wₑ) which, in the presence of objects O placed along the propagation direction of the acoustic wave, is reflected forming an ultrasonic echo (or reflected wave, indicated in FIG. 1 with the reference Wᵣ) detectable through the same ultrasonic transducer T; the time distance between the emission of the emitted wave Wₑ and the reception of the reflected wave NV, is indicative of a relative distance D between the ultrasonic transducer T and the detected object O. Consequently, by measuring the time-of-flight it is possible to have information about the object O to be detected. In greater detail, the ultrasonic transducer T comprises a membrane which, for example by piezoelectricity, is controllable to oscillate in order to generate the emitted wave Wₑ. This membrane is also configured to oscillate when the reflected wave NV, impinges on the ultrasonic transducer T; this allows therefore the reflected wave Wₑ to be detected, for example by piezoelectricity. In this case, the ultrasonic transducer T operates both as an emitter and as a receiver, at alternating times; nevertheless, it is similarly possible to have a first ultrasonic transducer T which operates as an emitter and a second ultrasonic transducer T which operates as a receiver, and which is arranged so as to detect the reflected wave Wᵣ caused by the emitted wave Wₑ generated by the first ultrasonic transducer T.

FIG. 2 schematically shows an ultrasonic transducer device 1 of a known type and made using MEMS technology, therefore hereinafter also referred to as MUT (“Micromachined Ultrasonic Transducer”) device.

For example, the MUT device 1 is integrated in a die comprising a semiconductor body 3 of semiconductor material, such as silicon, for example monolithic, having a first and a second main face 3A, 3B.

The MUT device 1 comprises a MEMS ultrasonic transducer element (or MUT element) 5 extending into the semiconductor body 3.

The MUT element 5 comprises a first buried chamber 15, arranged in proximity to the first main face 3A of the semiconductor body 3 and at a distance from the first main face 3A. The portion of the semiconductor body 3 present between the first chamber 15 and the first main face 3A of the semiconductor body 3 forms a membrane body 18 with a thickness along the Z axis which is uniform.

On the membrane body 18, over the first main face 3A, is arranged a piezoelectric element 19 of a known type which forms, together with the membrane body 18, a membrane 20. The piezoelectric element 19 comprises a layer of piezoelectric material such as PZT, interposed along the Z axis between two electrodes.

In use, the MUT device 1 is surrounded by a propagation means (a fluid such as liquid or gas, in particular air) wherein acoustic waves (in detail, ultrasonic waves) propagate, generated or detected by the MUT device 1, which may operate as an emitter and/or receiver. In particular, when the MUT device 1 operates as an emitter, the piezoelectric element 19 is biased through a drive signal so as to deform elastically to cause a respective elastic deformation of the membrane 20 (i.e., a vibration of the membrane 20). This generates acoustic waves that propagate through the propagation means. On the other hand, when the MUT device 1 operates as a receiver, the acoustic waves that reach the MUT device 1 propagating through the propagation means vibrate the membrane 20 and therefore cause an elastic deformation of the piezoelectric element 19, which generates a consequent electrical signal indicative of the detected acoustic waves.

In detail, both in the emission mode and in the reception mode, the membrane 20 vibrates at a vibration frequency which is about equal to a resonance frequency of the MUT device 1. The resonance frequency depends, in a per se known manner, on factors such as the geometry and materials of the MUT element 5 (e.g., shape and thickness of the membrane 20 and materials of the semiconductor body 3 and of the piezoelectric element 19).

Nevertheless, it is known to electrically control the MUT device 1 in such a way as to electrically modify its resonance frequency, to better adapt it to the required application so as to improve the performances of the MUT device.

For example, this is done in the MUT device 1 by applying to the piezoelectric element 19, in addition to the drive signal, also a modulation signal (e.g., of DC-type), in order to cause a respective and further elastic modulation deformation thereof, which adds to that generated by the piezoelectric element 19 or induced in the latter (in the emission and reception modes, respectively). In particular, the modulation signal is an electrical voltage of the DC-type, for example with a value greater than 0 V and specifically dependent on factors such as the application considered, the structure of the MUT device 1 and the materials wherewith it is made. The effect of the application of the modulation signal is to create an additional stress in the membrane 20 that modifies the mechanical and therefore vibrational properties of the membrane 20, causing a modification (i.e., “tuning”) of the resonance frequency.

On the other hand, other known solutions concern the use of one or more further piezoelectric elements on the membrane body 18, arranged side by side with the piezoelectric element 19. These further piezoelectric elements are electrically controlled independently from the piezoelectric element 19 (for example, through the modulation signal previously mentioned) and are used to generate an additional stress in the membrane 20 which modifies the mechanical and therefore vibrational properties of the membrane 20, causing a modification of the resonance frequency.

On the other hand, a further known solution (e.g., prior art document US 2013/0162102 A1) comprises the use of a bimorph structure for the piezoelectric element 19. In this solution, the piezoelectric element 19 comprises a plurality of electrode-PZT-electrode stacks superimposed on each other along the Z axis and electrically controllable independently from each other. In this manner, considering for example two superimposed stacks, one stack is used to generate the acoustic waves (e.g., it is biased with the drive signal) and the other stack is used to create the additional stress in the membrane 20 which modifies the mechanical and therefore vibrational properties of the membrane 20 (e.g., it is biased with the modulation signal).

However, in known solutions the frequency of the acoustic waves, measured between the MUT device 1 (i.e., the ultrasonic transducer T) and the object O to be detected, does not depend on their emission direction and therefore on the relative angle between the MUT device 1 and the object O. In detail, the relative angle between the MUT device 1 and the object O is given by a tilting angle θ defined between the emission direction 24 and a reference direction 22 orthogonal to the first main face 3A of the semiconductor body 3. For example, the emission direction 24 joins the object O (exemplarily considered point-like) and the MUT device 1 (for example, a center of the membrane 20, taken in an XY plane defined by the X and Y axes and parallel to the first main face 3A of the semiconductor body 3). In known solutions, the frequency of the acoustic waves is invariant with respect to the tilting angle θ.

This is a relevant limit of the known solutions since it prevents the MUT device 1 from performing selective measurements on a desired object O; conversely, in the presence of multiple objects O present in the field-of-view (FOV) of the MUT device 1, the latter detects only the object O closest to the MUT device 1. In other words and as shown in FIG. 3, when for example a first object O₁ and a second object O₂ are present in the FOV 26 of the MUT device 1 (the first object O₁ being at a null tilting angle θ and distant from the MUT device 1 by a first distance D₁ and the second object O₂ being at a non-null tilting angle θ and distant from the MUT device 1 by a second distance D₂ smaller than the first distance D₁), the MUT device 1 detects only the second distance D₂.

### BRIEF SUMMARY

The present disclosure is directed to a MEMS ultrasonic transducer device, a manufacturing process and a control method of the MEMS ultrasonic transducer device, which overcome the drawbacks of the prior art.

The present disclosure is directed to a MEMS ultrasonic transducer (MUT) wherein a support structure, has a first and a second main face opposite to each other along a first axis and at least one MUT element. The MUT element includes a modulation cavity which extends into the support structure from the second main face towards the first main face and a membrane body of the support structure, which extends along the first axis between the modulation cavity and the first main face and which is fixed to the support structure, the membrane body comprising a central portion and one or more extremal portions which are interposed, orthogonally to the first axis, between the central portion and the support structure and which mutually couple the central portion and the support structure, the central portion defining at least one transduction membrane body and the one or more extremal portions defining a modulation membrane body. There is a modulation membrane of the MUT element, suspended on the modulation cavity. There is at least one transduction cavity which extends into the central portion of the membrane body, the transduction membrane body extending along the first axis between the transduction cavity and the first main face. There is a transduction membrane of the MUT element, suspended on the transduction cavity and the modulation membrane body has a first thickness along the first axis, and the transduction membrane body has, along the first axis, a second thickness smaller than the first thickness.

### BRIEF DESCRIPTION OF THE SEVERAL VIEWS OF THE DRAWINGS

For a better understanding of the present disclosure, a preferred embodiment is now described, purely by way of non-limiting example, with reference to the attached drawings, wherein:

FIG. 1 schematically shows the operation of an ultrasonic transducer of a known type;

FIG. 2 is a cross-sectional view of a MEMS ultrasonic transducer, MUT, of a known type;

FIG. 3 schematically shows the type of detection operated by a MUT of a known type;

FIGS. 4-7 are cross-sectional views of respective embodiments of a MEMS ultrasonic transducer, MUT, device where FIGS. 4 and 5 are taken along a section line shown in FIG. 9A and FIGS. 6 and 7 are taken along a section line shown in FIG. 9B;

FIG. 8 is a cross-sectional view of a detail of the MUT device of FIGS. 4-7;

FIGS. 9A-9F are top views of respective embodiments of the present MUT device;

FIGS. 10A-10B are cross-sectional views of the MUT device of FIG. 6 that illustrate the operation thereof in two different states;

FIGS. 11A-11B are cross-sectional views of the MUT device of FIG. 7 that illustrate the operation thereof in two different states;

FIG. 12 is a graph showing, as a function of time, the displacement of a modulation membrane of the present MUT device;

FIGS. 13A-13D are cross-sectional views illustrating respective steps of a manufacturing process of the MUT device of FIG. 4;

FIGS. 14A-14D are cross-sectional views which illustrate respective steps of a manufacturing process of the MUT device of FIG. 5; and

FIG. 15 schematically shows the type of detection operated by the present MUT device.

### DETAILED DESCRIPTION

In particular, the Figures are shown with reference to a triaxial Cartesian system defined by an X axis, a Y axis and a Z axis (or first axis Z), orthogonal to each other.

In the following description, elements common to the different embodiments have been indicated with the same reference numbers.

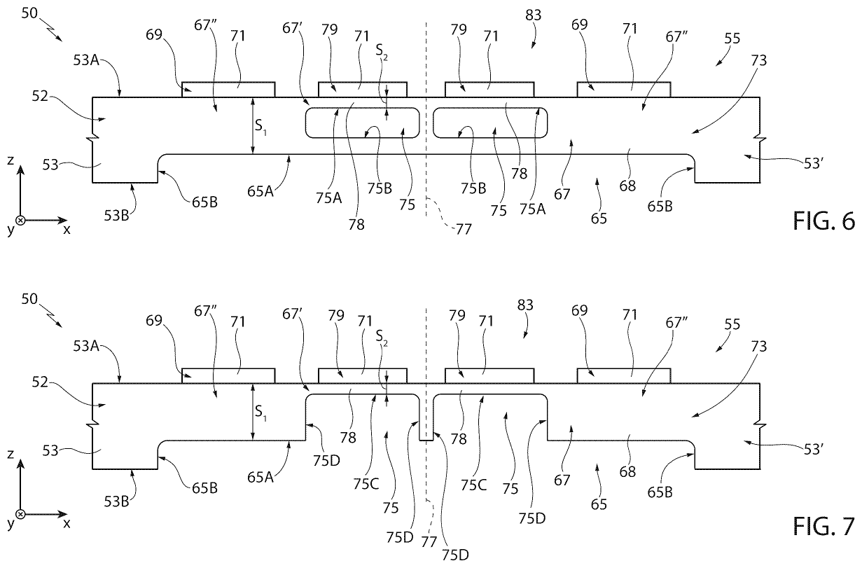

FIG. 4 schematically shows an ultrasonic transducer device 50 made using MEMS technology, and therefore hereinafter also referred to as MUT (“Micromachined Ultrasonic Transducer”) device.

For example, the MUT device 50 is integrated in a die 52. The die 52 comprises a semiconductor body 53 of semiconductor material, such as silicon, for example monolithic, having a first and a second main face (or surface) 53A, 53B opposite to each other along the Z axis.

The MUT device 50 integrates one or more MEMS ultrasonic transducer elements (or MUT elements) 55. In the embodiment exemplarily shown in FIG. 4 and discussed hereinbelow, the MUT device 50 comprises a single MUT element 55; nevertheless, the MUT device 50 may comprise a plurality of MUT elements 55.

The MUT element 55 is formed in the semiconductor body 53.

In particular, the MUT element 55 has a modulation cavity 65 which extends into the semiconductor body 53, from the second main face 53B of the semiconductor body 53 towards the first main face 53A of the semiconductor body 53, without reaching the latter. In detail, the modulation cavity 65 is upwardly delimited by a first bottom surface 65A of the semiconductor body 53 and is laterally delimited by first lateral surfaces 65B of the semiconductor body 53 which join the first bottom surface 65A of the semiconductor body 53 with the second main face 53B of the semiconductor body 53. In other words, the modulation cavity 65 has the first bottom surface 65A and, opposite thereto along the Z axis, an opening wherethrough the modulation cavity 65 communicates with the outside of the MUT device 50.

The portion of the semiconductor body 53 extending between the modulation cavity 65 and the first main face 53A of the semiconductor body 53 forms a membrane body 67 of the MUT element 55.

In particular, the semiconductor body 53 defines a support structure 53′ which supports and anchors the membrane body 67 in such a way that the latter is suspended on the modulation cavity 65. In use, the membrane body 67 oscillates relatively to the support structure 53′.

In detail, the membrane body 67 comprises a central portion 67′ defining a transduction membrane body 78, and one or more extremal portions 67″ defining a modulation membrane body 68. The extremal portions 67″ of the membrane body 67 are interposed between the central portion 67′ of the membrane body 67 and the support structure 53′, so as to couple the latter to each other. In greater detail, the central portion 67′ of the membrane body 67 is interposed, orthogonally to the Z axis (e.g., along the X axis), between the extremal portions 67″ of the membrane body 67; in other words, the transduction membrane body 78 is, orthogonally to the Z axis, internal and, in detail, central with respect to the modulation membrane body 68.

More in detail, the modulation membrane body 68 has a thickness, along the Z axis, equal to a first thickness S₁. In greater detail, the first thickness S₁ is measured along the Z axis between the first main face 53A of the semiconductor body 53 and the first bottom surface 65A. For example, the first thickness S₁ is comprised between about 5 μm and about 50 μm, in particular between about 10 μm and about 20 μm. In particular, the modulation membrane body 68 has a thickness, along the Z axis, that is substantially uniform; for example, the first thickness S₁ is the minimum thickness of the modulation membrane body 68 along the Z axis.

A piezoelectric modulation structure 69 of the MUT element 55 is present on the modulation membrane body 68, above the first main face 53A. The piezoelectric modulation structure 69 forms, together with the modulation membrane body 68, a modulation membrane 73 of the MUT element 55. In particular, the piezoelectric modulation structure 69 comprises one or more piezoelectric elements 71 configured to vibrate the modulation membrane 73, as better described hereinbelow.

The MUT element 55 also has a transduction cavity 75 that extends into the central portion 67′ of the membrane body 67.

In the embodiment of FIG. 4, the transduction cavity 75 is of the buried type and, for example, is arranged at the first main face 53A of the semiconductor body 53. In detail, the transduction cavity 75 extends into the semiconductor body 53 so as to be surrounded by the latter, and therefore to be buried therein and insulated (i.e., not communicating) with respect to an environment external to the MUT device 50. For example, the transduction cavity 75 is closer to the first main face 53A of the semiconductor body 53 than to the first bottom surface 65A. In detail, the transduction cavity 75 is upwardly delimited by a first cavity surface 75A of the semiconductor body 53 and is downwardly delimited by a second cavity surface 75B of the semiconductor body 53, opposite to each other along the Z axis with respect to the transduction cavity 75.

The portion of the semiconductor body 53 (in detail, of the central portion 67′ of the membrane body 67) extending between the transduction cavity 75 and the first main face 53A of the semiconductor body 53 forms the transduction membrane body 78.

In detail, the transduction membrane body 78 has a thickness, along the Z axis, equal to a second thickness S₂ lower than the first thickness S₁. In greater detail, the second thickness S₂ is measured along the Z axis between the first main face 53A of the semiconductor body 53 and the first cavity surface 75A of the semiconductor body 53. For example, the second thickness S₂ is comprised between about 500 nm and about 81 μm, in particular between about 11 μm and about 21 μm. In particular, the transduction membrane body 78 has a thickness, along the Z axis, that is substantially uniform; for example, the second thickness S₂ is the maximum thickness of the transduction membrane body 78 along the Z axis.

A piezoelectric transduction structure 79 of the MUT element 55 is present on the transduction membrane body 78, above the first main face 53A. The piezoelectric transduction structure 79 forms, together with the transduction membrane body 78, a transduction membrane 83 of the MUT element 55. In particular, the piezoelectric transduction structure 79 comprises one or more piezoelectric elements 71 configured to generate and/or detect vibrations of the transduction membrane 83, as better described hereinbelow.

The piezoelectric transduction structure 79 is superimposed, along the Z axis, on the transduction cavity 75 and is arranged side by side, orthogonally to the Z axis (e.g., along the X axis), to the piezoelectric modulation structure 69 which is instead vertically staggered with respect to the transduction cavity 75 (i.e., it is not superimposed, along the Z axis, on the transduction cavity 75).

In detail, the MUT element 55 may have axial symmetry along a central axis 77 parallel to or coincident with the Z axis.

In greater detail, the transduction cavity 75 and the modulation cavity 65 are concentric and coaxial along the central axis 77. In other words, the transduction cavity 75 and the modulation cavity 65 (here exemplarily considered with a circular shape orthogonally to the Z axis) have, orthogonally to the Z axis, centers that are aligned with each other along the central axis 77. The transduction membrane body 78 and the modulation membrane body 68 are therefore also concentric and coaxial with each other and with respect to the transduction cavity 75 and the modulation cavity 65 and, in the example considered, they also have a circular shape. In detail, the modulation membrane body 68 is radially external to the transduction membrane body 78 with respect to the central axis 77.

For example, the transduction membrane body 78 has, parallel to the XY plane (therefore orthogonally to the Z axis), a smaller area than the modulation membrane body 68; similarly, the transduction cavity 75 has, parallel to the XY plane, a smaller area than the modulation cavity 65.

Furthermore, for example, the cavities 65, 75 and therefore the respective membrane bodies 68, 78 have an area (parallel to the XY plane) that is greater with respect to the area of the respective piezoelectric structures 69, 79, such that their peripheral zones, here exemplarily having the shape of a circular ring, protrude laterally with respect to the respective piezoelectric structures 69, 79.

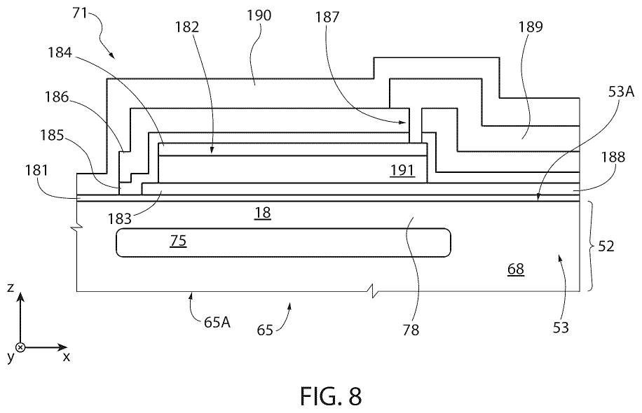

FIG. 5 shows a further embodiment of the MUT device 50.

The MUT device 50 of FIG. 5 is similar to that of FIG. 4, however the transduction cavity 75 is not of the buried type but of the exposed type and faces (i.e., communicates with) the modulation cavity 65.

In detail, the transduction cavity 75 extends into the membrane body 67, from the first bottom surface 65A towards the first main face 53A of the semiconductor body 53, without reaching the latter. In detail, the transduction cavity 75 is upwardly delimited by a second bottom surface 75C of the semiconductor body 53, whose distance along the Z axis from the first main face 53A of the semiconductor body 53 defines the second thickness S₂; furthermore, the transduction cavity 75 is laterally delimited by second lateral surfaces 75D of the semiconductor body 53 which join the third bottom surface 75C with the first bottom surface 65A. In other words, the transduction cavity 75 has the second bottom surface 75C and, opposite thereto along the Z axis, an opening which extends through the first bottom surface 65A and wherethrough the transduction cavity 75 communicates with the modulation cavity 65. The cavities 65 and 75 are therefore axially adjacent along the central axis 77.

In detail, the first bottom surface 65A and the second bottom surface 75C are part of a rear surface of the membrane body 67, having variable height along the Z axis and in particular having two levels (an internal level and an external level which is radially external to the internal level and is axially more distant from the first main face 53A than the internal level).

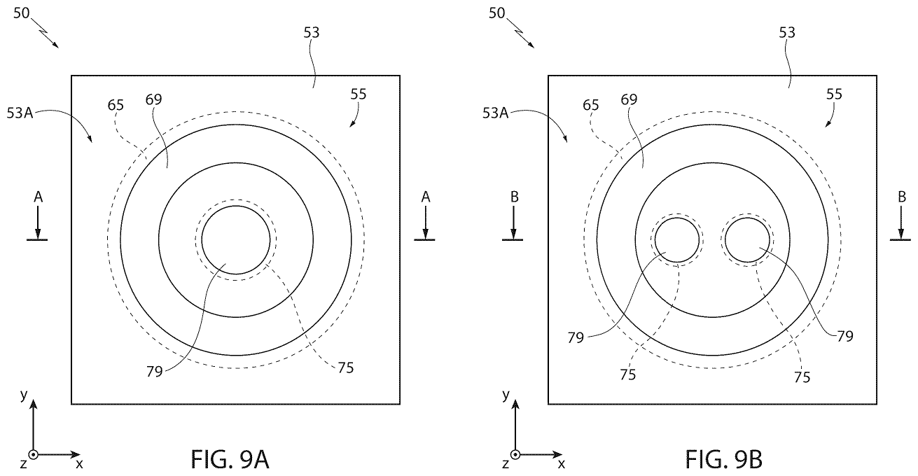

FIG. 6 shows a further embodiment of the MUT device 50.

The MUT device 50 of FIG. 6 is similar to that of FIG. 4, however a plurality of transduction cavities 75 of the buried type are present in the central portion 67′ of the membrane body 67, instead of just one. By way of example, FIG. 6 shows two transduction cavities 75; nevertheless, the number of transduction cavities 75 may similarly be greater.

In detail, the transduction cavities 75 are arranged side by side to each other orthogonally to the Z axis (e.g., along the X axis) and are spaced from each other so as to be insulated from each other.

The portions of the semiconductor body 53 extending between each transduction cavity 75 and the first main face 53A of the semiconductor body 53 form respective transduction membrane bodies 78 with a thickness, along the Z axis, equal to the second thickness S₂.

A respective piezoelectric transduction structure 79 of the MUT element 55 is present on each transduction membrane body 78, above the first main face 53A. The piezoelectric transduction structures 79 are arranged side by side to each other orthogonally to the Z axis (e.g., along the X axis), in particular at a distance from each other, and form, together with the respective transduction membrane bodies 78, respective transduction membranes 83 of the MUT element 55. In particular, each piezoelectric transduction structure 79 comprises one or more of said piezoelectric elements 71 configured to generate and/or detect vibrations of the respective transduction membrane 83.

The piezoelectric transduction structures 79 are therefore superimposed, along the Z axis, on the respective transduction cavities 75 and are arranged side by side, orthogonally to the Z axis (e.g., along the X axis), to the piezoelectric modulation structure 69 which is instead vertically staggered with respect to the transduction cavities 75.

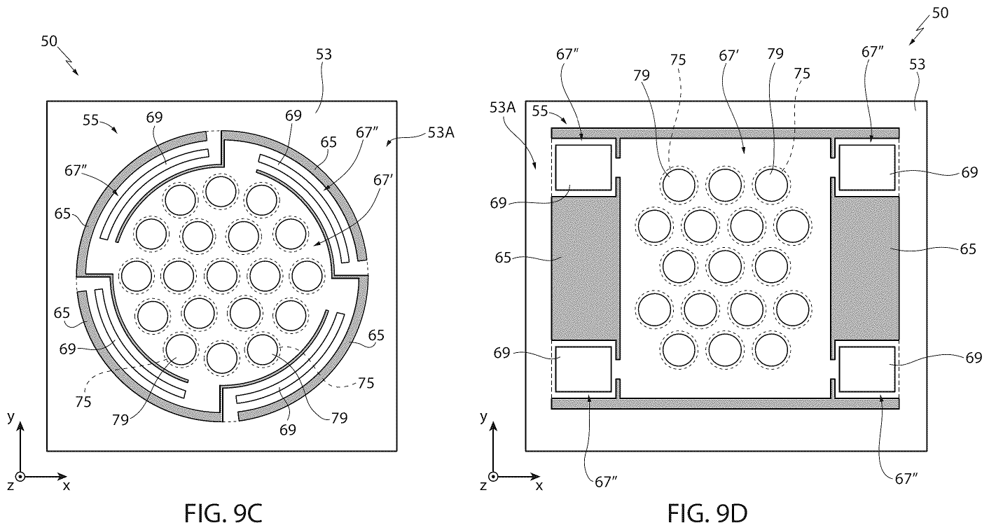

FIG. 7 shows a further embodiment of the MUT device 50.

The MUT device 50 of FIG. 7 is similar to that of FIG. 5, however a plurality of transduction cavities 75 of the exposed type are present in the central portion 67′ of the membrane body 67, instead of just one. By way of example, FIG. 7 shows two transduction cavities 75; nevertheless, the number of transduction cavities 75 may similarly be greater.

In detail, the transduction cavities 75 are arranged side by side to each other orthogonally to the Z axis (e.g., along the X axis) and are spaced from each other so as to be insulated from each other.

The portions of the semiconductor body 53 extending between each transduction cavity 75 and the first main face 53A of the semiconductor body 53 form respective transduction membrane bodies 78 with a thickness, along the Z axis, equal to the second thickness S₂.

A respective piezoelectric transduction structure 79 of the MUT element 55 is present on each transduction membrane body 78, above the first main face 53A. The piezoelectric transduction structures 79 are arranged side by side to each other orthogonally to the Z axis (e.g., along the X axis), in particular at a distance from each other, and form, together with the respective transduction membrane bodies 78, respective transduction membranes 83 of the MUT element 55. In particular, each piezoelectric transduction structure 79 comprises one or more of said piezoelectric elements 71 configured to generate and/or detect vibrations of the respective transduction membrane 83.

The piezoelectric transduction structures 79 are therefore superimposed, along the Z axis, on the respective transduction cavities 75 and face, orthogonally to the Z axis (e.g., along the X axis), the piezoelectric modulation structure 69 which is instead vertically staggered with respect to the transduction cavities 75.

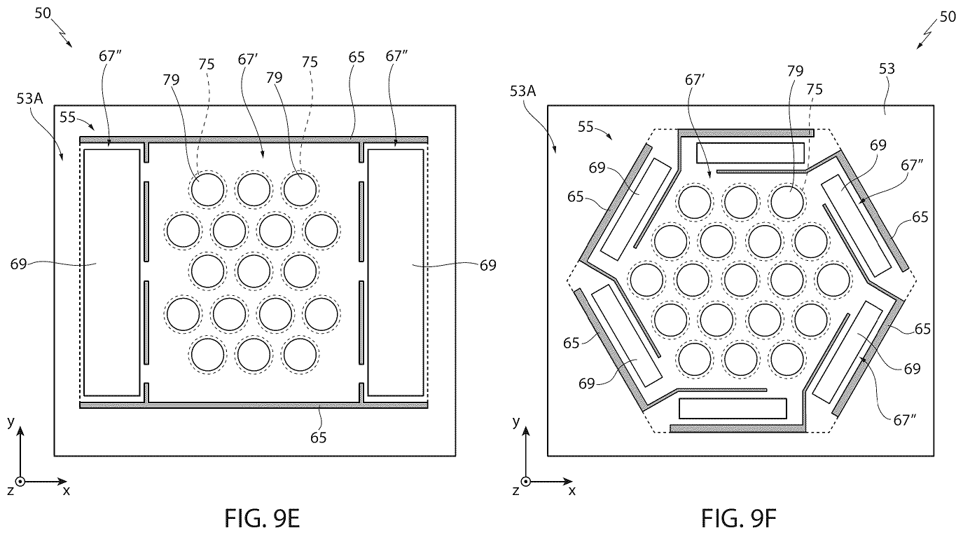

FIG. 8 shows, by way of non-limiting example, an example of structure of the piezoelectric element 71 of the piezoelectric modulation structure 69 and of the piezoelectric transduction structure 79. For example, FIG. 8 exemplarily shows the piezoelectric element 71 of the piezoelectric transduction structure 79.

In detail, the piezoelectric element 71 is formed above an insulating layer 181, for example formed by the superimposition of a thermally grown silicon oxide layer and a dielectric layer, and covers the entire first main face 53A of the semiconductor body 53. Above the insulating layer 181, there extends a stack 182 comprising: a bottom electrode 183, of electrically conductive material, for example of titanium (Ti) or platinum (Pt); a thin-film piezoelectric region 191; and a top electrode 184, for example of TiW. The bottom electrode 183 is in electrical contact with a first contact line 188 (for example, it is formed in the same layer and patterned through known photolithographic steps). A first and a second dielectric layer 185, 186, for example of silicon oxide and silicon nitride deposited by CVD (Chemical Vapor Deposition) extend on the stack 182. A second contact line 189 of conductive material, for example of aluminum and/or copper, extends above the dielectric layers 185, 186 and into an opening 187 thereof, to electrically contact the top electrode 184. Optionally, a passivation layer 190, for example of silicon oxide and/or nitride deposited by CVD, covers all the top surface of the die 52, except for the electrical connection openings (above contact pads of the MUT element 55). In practice, the contact lines 188, 189 form electrical connections and allow: in order to generate the emitted wave Wₑ by the MUT element 55, the electrical connection of one of the electrodes 183, 184 (for example the bottom electrode 183) to a reference potential, typically to ground, and the biasing of the other of the electrodes 183, 184 (for example of the top electrode 184) to an AC actuation voltage; or, in order to detect the reflected wave Wᵣ, the acquisition of a detection potential difference between the electrodes 183 and 184 induced by the impingement of the reflected wave Wᵣ on the transduction membrane 83.

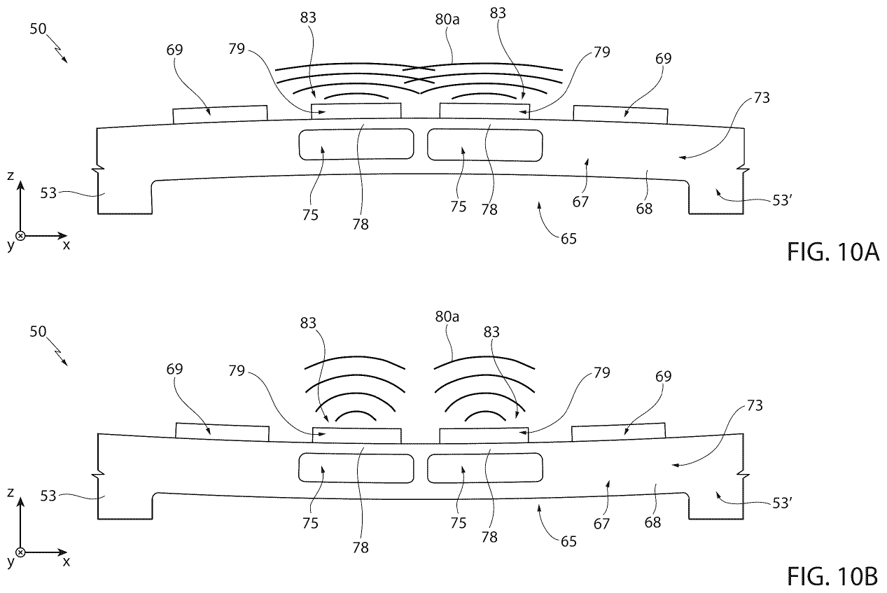

FIGS. 9A-9F schematically show top views of the MUT device 50. In other words, these views are taken orthogonally to the Z axis, i.e., parallel to the XY plane.

In particular, FIG. 9A shows a top view of the MUT device 50 of FIG. 4 or 5. As exemplarily shown in FIG. 9A, the transduction membrane body 78, the piezoelectric transduction structure 79, the transduction cavity 75, the modulation membrane body 68, the piezoelectric modulation structure 69 and the modulation cavity 65 have, parallel to the XY plane, a substantially circular shape and are concentric with each other.

FIG. 9B shows a top view of the MUT device 50 of FIG. 6 or 7. As exemplarily shown in FIG. 9B, the transduction membrane body 78, the piezoelectric transduction structures 79, the transduction cavities 75, the modulation membrane body 68, the piezoelectric modulation structure 69 and the modulation cavity 65 have, parallel to the XY plane, a substantially circular shape. The piezoelectric modulation structure 69, the modulation membrane body 68 and the modulation cavity 65 are concentric with each other, as well as each piezoelectric transduction structure 79 with the respective transduction membrane body 78 and the respective transduction cavity 75. In particular, the transduction membrane bodies 78 are surrounded by the modulation membrane body 68 which joins them to the support structure 53′.

Although FIGS. 9A and 9B show circular shapes of the illustrated elements, other closed polygonal shapes may be similarly used (e.g., triangular, square, hexagonal shape, etc.). Furthermore, other shapes and arrangements of the piezoelectric modulation structure 69 and the modulation cavity 65 relative to the piezoelectric transduction structures 79 and the transduction cavities 75 are possible.

For example, in the embodiment of FIG. 9C the modulation membrane body 68 is formed by a plurality of said extremal portions 67″ of the membrane body 67. In top view, the central portion 67′ of the membrane body 67 has a circular shape and the extremal portions 67″ have an annular sector shape and are arranged circumferentially one adjacent to the other. In particular, each extremal portion 67″ has a first end and a second end that are opposite to each other along the main extension of the extremal portion 67″ (i.e., circumferentially to the central portion 67′); the extremal portions 67″ are fixed to the support structure 53′ through the respective first ends and are fixed to the central portion 67′ of the membrane body 67 through the respective second ends. Furthermore, the central portion 67′ of the membrane body 67 comprises a plurality of transduction cavities 75, for example arranged substantially homogeneously in the central portion 67′, and therefore comprises a respective plurality of transduction membrane bodies 78, each vertically overlaid by the respective piezoelectric transduction structure 79.

In the embodiment of FIG. 9D, the central portion 67′ has a quadrangular, in particular square, shape. The modulation membrane body 68 is formed by a plurality of said extremal portions 67″ of the membrane body 67, connected to the vertices of the central portion 67′. For example, the extremal portions 67″ also have a quadrangular, in particular square or rectangular, shape, and have the respective first ends fixed to the support structure 53′ and the respective second ends fixed to the vertices of the central portion 67′. Similarly to FIG. 9C, the central portion 67′ of the membrane body 67 comprises a plurality of transduction cavities 75 (and therefore of transduction membrane bodies 78), for example arranged substantially homogeneously in the central portion 67′.

In the embodiment of FIG. 9E, the central portion 67′ has a quadrangular, in particular square, shape. The modulation membrane body 68 is formed by two extremal portions 67″ of the membrane body 67, for example of quadrangular (in particular, rectangular) shape, which have a longitudinal extension substantially equal to the length of the sides of the central portion 67′ and which are respectively connected to sides, opposite to each other, of the central portion 67′. Similarly to FIG. 9C, the central portion 67′ of the membrane body 67 comprises a plurality of transduction cavities 75 (and therefore of transduction membrane bodies 78), for example arranged substantially homogeneously in the central portion 67′.

In the embodiment of FIG. 9F, the modulation membrane body 68 is formed by a plurality of said extremal portions 67″ of the membrane body 67. In top view, the central portion 67′ of the membrane body 67 has a hexagonal shape and the extremal portions 67″ have a substantially rectangular shape and are each arranged side by side to a respective side of the central portion 67′, so as to be arranged circumferentially one adjacent to the other. In particular, the extremal portions 67″ are fixed to the support structure 53′ through the respective first ends and are fixed to the vertices of the central portion 67′ of the membrane body 67 through the respective second ends. Similarly to FIG. 9C, the central portion 67′ of the membrane body 67 comprises a plurality of transduction cavities 75 (and therefore of transduction membrane bodies 78), for example arranged substantially homogeneously in the central portion 67′.

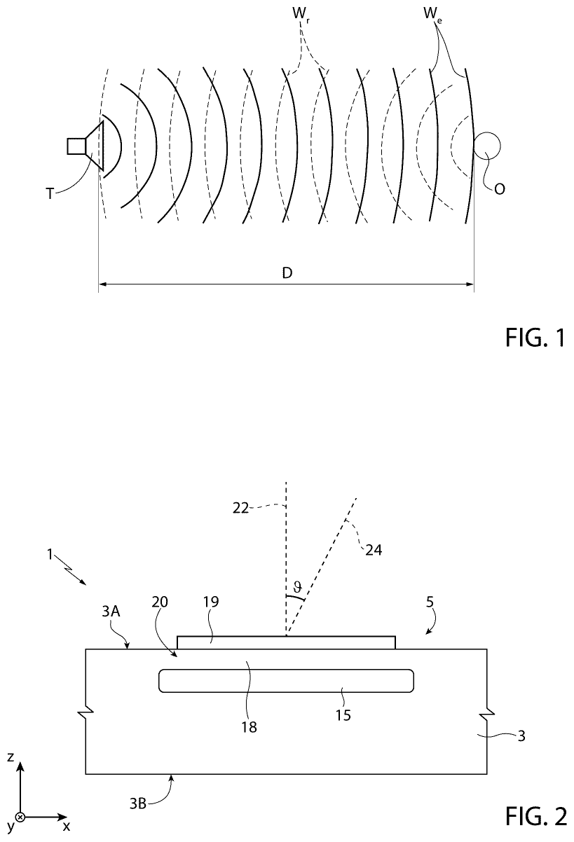

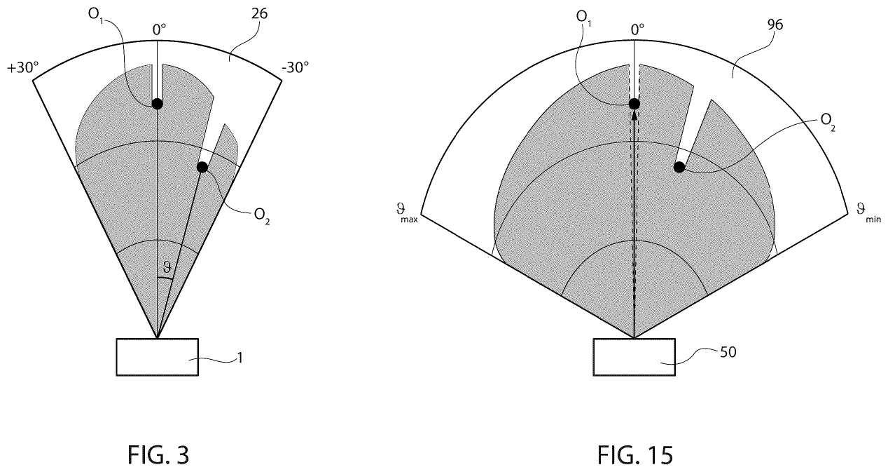

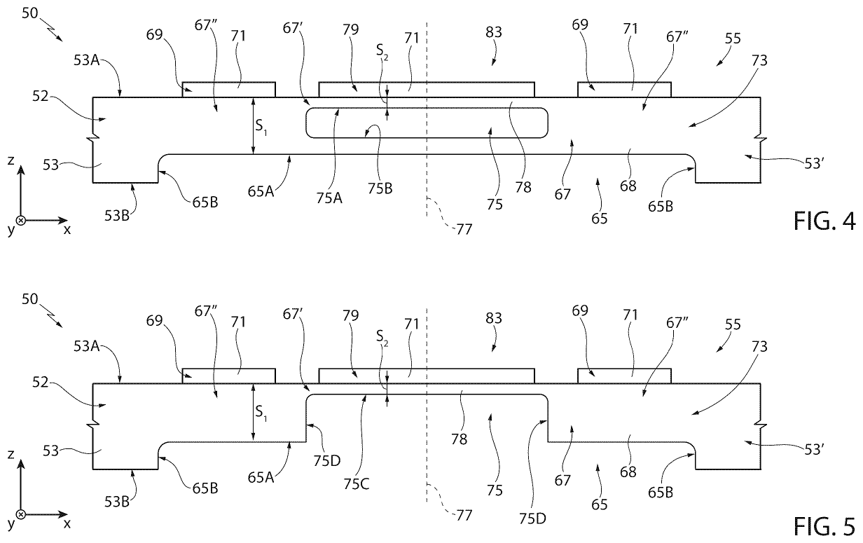

In use, the MUT device 50 operates in a similar manner to the known devices (e.g., the ultrasonic transducer T of FIG. 1). In particular, in use the MUT device 50 is surrounded by a propagation means (a fluid such as liquid or gas, in particular air) wherein acoustic waves (in detail, ultrasonic waves), generated or detected by the MUT device 50, propagate.

When the MUT element 55 is operated in an own emission mode (i.e., it works as an actuator), the membranes 73 and 83 are vibrated by the respective piezoelectric structures 69 and 79 and, as better described hereinbelow, the vibrations of the one or more transduction membranes 83 (relative to rest positions thereof) cause the generation and propagation in the propagation means of the acoustic waves.

In particular, a first actuation voltage, of the AC-type (e.g., at a first actuation frequency comprised between about 1 kHz and about 100 kHz, for example equal to about 10 kHz, and with a voltage equal to about 40 V), is applied between the electrodes 183 and 184 of the one or more piezoelectric elements 71 of the piezoelectric modulation structure 69 while a second actuation voltage, of the AC-type (e.g., at a second actuation frequency higher than the first actuation frequency and comprised between about 500 kHz and about 50 MHz, for example equal to about 5 MHz, and with a voltage equal to about 40 V), is applied between the electrodes 183 and 184 of the one or more piezoelectric elements 71 of the piezoelectric transduction structure 79. The application of the first actuation voltage causes, alternately, the contraction and expansion of the thin-film piezoelectric region 191 of the piezoelectric modulation structure 69 and therefore the resulting deflection of the modulation membrane 73 in the vertical direction, alternately moving away from and towards the modulation cavity 65. The application of the second actuation voltage causes, alternately, the contraction and expansion of the thin-film piezoelectric region 191 of the piezoelectric transduction structure 79 and therefore the resulting deflection of the transduction membrane 83 in the vertical direction, alternately moving away from and towards the transduction cavity 75. Since the first actuation frequency is much lower than the second actuation frequency (e.g., by about two orders of magnitude), the vibration of the modulation membrane 73 occurs in a much slower manner than the vibration of the transduction membrane 83 (i.e., the first vibration frequency of the modulation membrane 73 is lower, e.g., by about two orders of magnitude, with respect to the second vibration frequency of the transduction membrane 83). In particular, the first vibration frequency is equal to the first actuation frequency and the second vibration frequency is equal to the second actuation frequency. The simultaneous vibration of the membranes 73 and 83 causes the generation of acoustic waves which propagate in the propagation means from the MUT device 50 and which simultaneously depend on the movement of both membranes 73 and 83.

In particular, the vibrational movement of the modulation membrane 73 adds to the vibrational movement of the transduction membrane 83, thus generating a modulation of the frequency of the acoustic waves emitted with respect to the known case wherein the sole vibrational movement of the transduction membrane 83 (hereinafter referred to as acoustic wave reference frequency) is present.

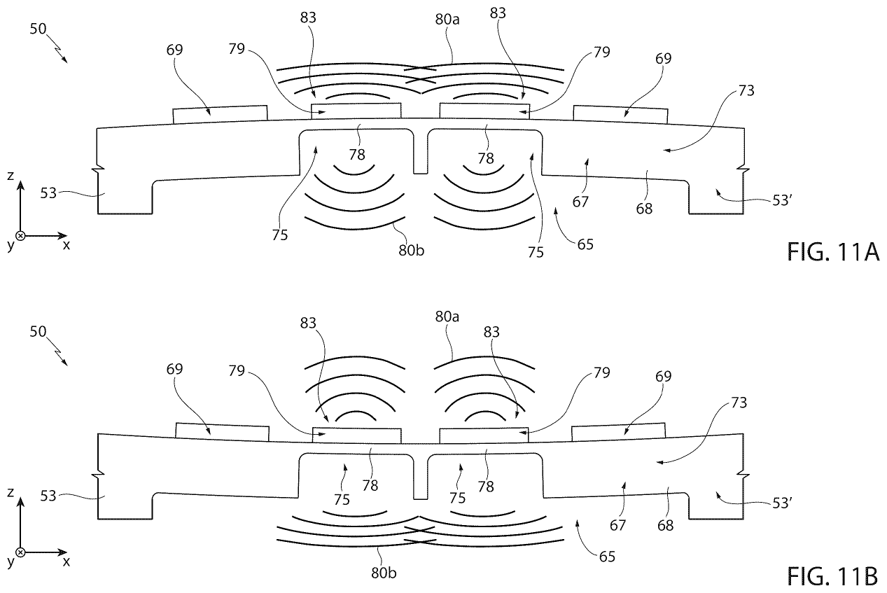

In fact, as exemplarily shown in FIGS. 10A and 10B exemplarily referring to the embodiment of the MUT device 50 of FIG. 6, when the modulation membrane 73 deforms in the opposite direction with respect to the modulation cavity 65 (FIG. 10A), the wavefronts propagating in the opposite direction with respect to the modulation cavity 65 (hereinafter also referred to as first wavefronts of the first acoustic waves 80a) are closer to each other since the movement of the modulation membrane 73 is concordant with the propagation direction of the first acoustic waves 80a; consequently, the frequency of the first acoustic waves 80a is higher than the reference frequency. On the other hand, when the modulation membrane 73 deforms towards the modulation cavity 65 (FIG. 10B), the first wavefronts are more spaced from each other since the movement of the modulation membrane 73 is discordant with the propagation direction of the first acoustic waves 80a; consequently, the frequency of the first acoustic waves 80a is lower than the reference frequency.

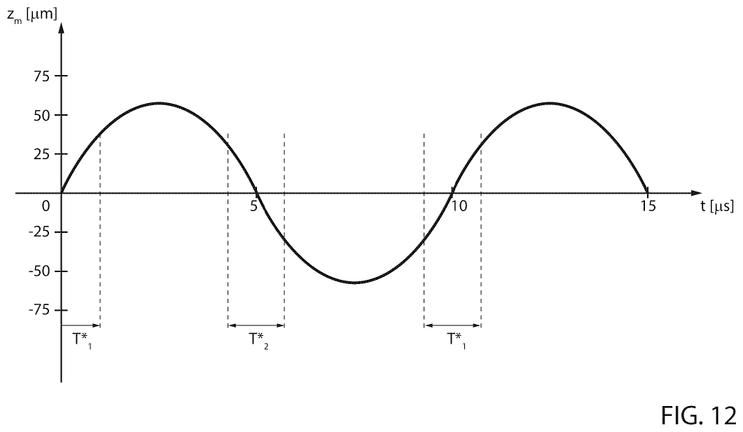

On the other hand, FIGS. 11A and 11B show the operation of the MUT device 50 of FIG. 7. In this case, the behavior of the acoustic waves 80a (emitted from the front of the MUT device 50) is similar to that described with reference to FIGS. 10A and 10B. Furthermore, since the transduction cavities 75 are exposed towards the back of the MUT device 50 and face the modulation cavity 65, the vibrations of the transduction membranes 83 also generate second acoustic waves 80b which propagate through the modulation cavity 65. In particular, when the modulation membrane 73 deforms in the opposite direction with respect to the modulation cavity 65 (FIG. 11A), the second wavefronts of the second acoustic waves 80b are more spaced from each other since the movement of the modulation membrane 73 is discordant with the propagation direction of the second acoustic waves 80b; consequently, the frequency of the second acoustic waves 80b is lower than the reference frequency. On the other hand, when the modulation membrane 73 moves towards the modulation cavity 65 (FIG. 11B), the second wavefronts are closer to each other since the movement of the modulation membrane 73 is concordant with the propagation direction of the second acoustic waves 80b; consequently, the frequency of the second acoustic waves 80b is higher than the reference frequency.

In other words, the vibrational movement of the modulation membrane 73 modulates the frequency of the acoustic waves 80a, 80b through Doppler effect. The Doppler effect is the change in the frequency of a wave in relation to an observer moving with respect to the wave source (or vice versa). In this case, it is the wave source (i.e., the modulation membrane 73) that moves with respect to the observer (e.g., the object to be detected), thus generating the Doppler effect. This means that the frequency of the acoustic waves depends on the emission direction, as better described hereinbelow.

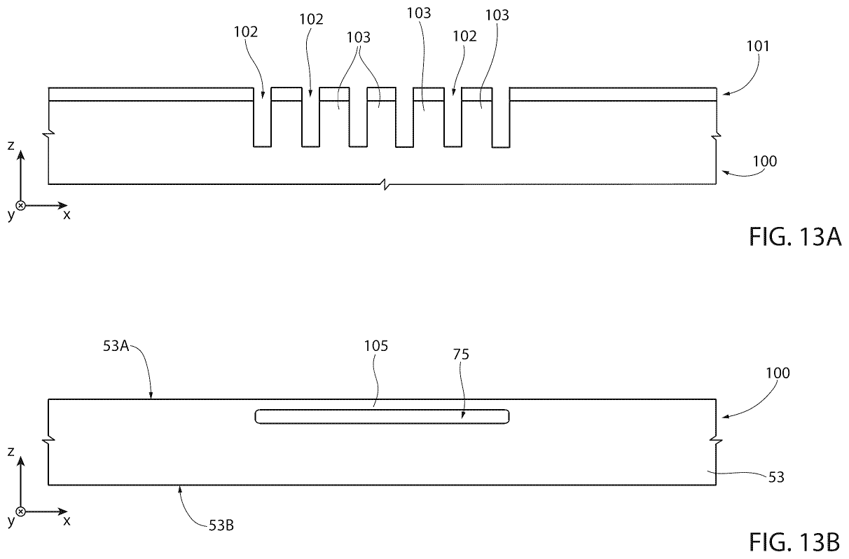

In detail, FIG. 12 shows the vibrational movement of the modulation membrane 73, in particular shows, as a function of time, the displacement Zₘ of the modulation membrane 73 along the Z axis with respect to its rest position (defined when the first actuation voltage is not applied). The vibrational movement of the modulation membrane 73 is of substantially sinusoidal type around its rest position (considered null in FIG. 12). Consequently, the MUT device 50 may be used in emission mode in predefined and periodic time intervals T*, wherein the modulation membrane 73 moves along the Z axis in an approximately linear manner; in particular, the time intervals T* are the time intervals wherein the displacement Zₘ of the modulation membrane 73 is comprised between about 60% of its maximum value and about 60% of its minimum value, or vice versa, and wherein, at a central instant of each time interval T*, the modulation membrane 73 is in its rest position. In other words, in the time intervals T* the displacement Zₘ is substantially linear in time. Therefore, in first time intervals T*₁ wherein the modulation membrane 73 moves in the opposite direction with respect to the modulation cavity 65, the MUT device 50 operates in linearity as previously described with reference to FIGS. 10A and 11A (therefore the frequency of the first acoustic waves 80a is higher and, possibly, the frequency of the second acoustic waves 80b is lower), while in second time intervals T*₂ wherein the modulation membrane 73 moves towards the modulation cavity 65, the MUT device 50 operates in linearity as previously described with reference to FIGS. 10B and 11B (therefore the frequency of the first acoustic waves 80a is lower and, possibly, the frequency of the second acoustic waves 80b is higher).

On the other hand, when the MUT element 55 is operated in an own reception mode (i.e., it works as a sensor), the acoustic waves coming from the propagation means (i.e., the reflected waves Wᵣ) impinge on the one or more transduction membranes 83 and induce the vibration thereof. This vibration causes a stress in the piezoelectric element 71 of one or more piezoelectric transduction structures 79 which in turn generate electrical potential differences between the electrodes 183 and 184, indicative of the vibration of the transduction membrane 83 induced by the impinging acoustic waves. In particular, the frequency of the induced vibration of each transduction membrane 83 may be modulated by vibrating the modulation membrane 73 as previously described, i.e., by biasing each piezoelectric modulation structure 69 through the first actuation voltage and measuring the electric potential differences induced in the piezoelectric transduction structures 79 during the time intervals T*. Therefore, considerations on the Doppler effect, which are similar to those previously discussed with reference to the emission mode, also apply to the reception mode.

The reception mode and the emission mode are alternative to each other: the MUT device 50 may therefore operate only in reception, only in emission, or both in reception and in emission but in time periods alternating to each other.

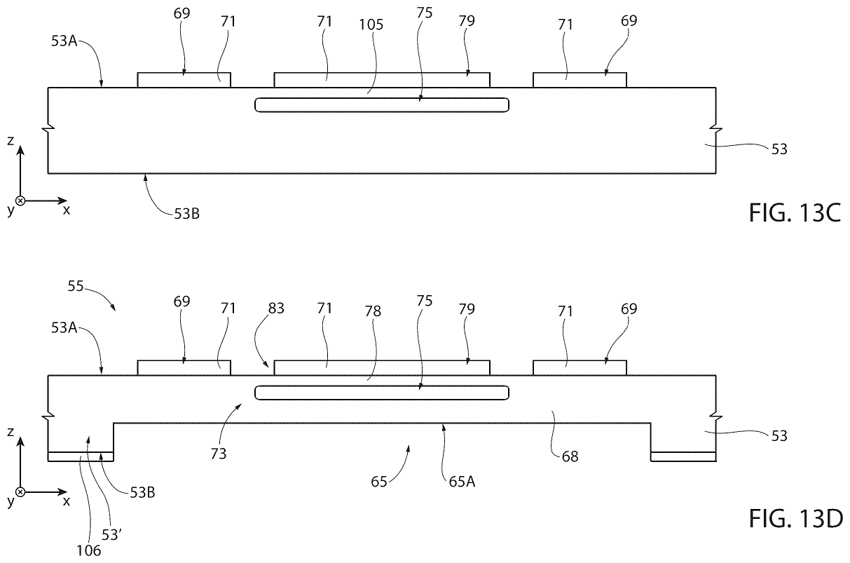

FIGS. 13A-13D show steps of a manufacturing process of the MUT device 50 of FIG. 4.

Initially, FIG. 13A, the transduction cavity 75 is formed in a wafer 100 of semiconductor material, for example monocrystalline silicon. For example, the manufacturing process described in the European patent EP1577656 and briefly summarized below may be used for this purpose.

In detail, a first mask 101 of resist having, at a region of the wafer 100 intended to accommodate the transduction cavity 75, openings arranged for example in a honeycomb lattice, is formed above the wafer 100 (i.e., on one top surface thereof). An anisotropic chemical etch of the wafer 100 is performed, by using the first mask 101, so as to form a plurality of trenches 102, having a depth of for example 10 μm, communicating with each other and delimiting a plurality of pillars (also called pillar structures) 103 of silicon.

Subsequently, FIG. 13B, the first mask 101 is removed and an epitaxial growth is performed in a reducing environment. Consequently, an epitaxial layer, for example of the N-type and of a thickness of about 10 μm, grows above the pillars 103, closing the trenches 102 upwardly.

An annealing step is then performed, for example for 30 minutes at 1190° C., preferably in a hydrogen, or, alternatively, nitrogen atmosphere.

As discussed in the abovementioned document, the annealing step causes a migration of the silicon atoms which tend to move to a lower energy position. Consequently, also owing to the close distance between the pillars 103, the silicon atoms thereof migrate completely and the transduction cavity 75 is formed. A silicon layer with the second thickness S₂ along the Z axis, formed in part by epitaxially grown silicon atoms and in part by migrated silicon atoms and forming a closing layer 105 of monocrystalline silicon (which will become the transduction membrane body 78), remains above the transduction cavity 75. The wafer 100 thus processed forms the semiconductor body 53.

Then, FIG. 13C, the piezoelectric elements 71 of the piezoelectric structures 69 and 79 are formed on the first main face 53A of the semiconductor body 53, in a per se known manner. In particular, the piezoelectric elements 71 are arranged side by side to each other along the X axis in such a way that the piezoelectric element 71 of the piezoelectric transduction structure 79 is vertically superimposed (along the Z axis) on the transduction cavity 75 while the one or more piezoelectric elements 71 of the piezoelectric modulation structure 69 are vertically staggered with respect to the transduction cavity 75.

For example and in a manner not shown in detail in FIG. 13C, a first dielectric layer is deposited, on the first main face 53A of the semiconductor body 53, which forms the insulating layer 181, for example comprising insulating material such as SiO₂ and for example with a thickness of about 1 μm; in particular, this occurs by performing a thermal oxidation process of the wafer 100 which leads to the formation of the first dielectric layer on the first main face 53A of the semiconductor body 53 and of a second dielectric layer (similar to the first dielectric layer) on the second main face 53B of the semiconductor body 53. The piezoelectric elements 19 are formed on the insulating layer 181. For example, firstly the electrodes 183 and the first contact lines 188 are formed, by using known deposition and masking techniques. Then, a thin-film piezoelectric layer (for example of PZT—Pb, Zr, TiO₃) and an electrode layer are deposited in succession, which are defined by known masking and definition techniques so as to form the thin-film piezoelectric regions 191 and the top electrodes 184. Then, the first and the second dielectric layers 185, 186 are deposited and defined, forming the openings 187; the second contact lines 189 are formed and the passivation layer 190 is deposited and defined, thus being opened on the contact pads (not shown).

Then, FIG. 13D, the modulation cavity 65 is formed by performing a first deep etch of the silicon from the back, at the second main face 53B of the semiconductor body 53.

In particular, the second dielectric layer is processed, through known oxide patterning techniques, to provide a second mask 106 of oxide having an opening that exposes the region of the semiconductor body 53 to be removed to form the modulation cavity 65. In detail, this region is aligned along the Z axis with the piezoelectric structures 69 and 79 and therefore with the transduction cavity 75. The first deep etch (e.g., anisotropic chemical etch) of the semiconductor body 53 is performed, by using the second mask 106, so as to form the modulation cavity 65 having a depth along the Z axis such as to define the modulation membrane body 68 having the first thickness S₁.

After carrying out the final manufacturing steps, including opening the contacts and dicing the wafer 100, the MUT device 50 of FIG. 4 is obtained.

Similarly, the MUT device 50 of FIG. 6 may also be obtained, in particular by forming multiple transduction cavities 75 arranged side by side to each other along the X axis and forming respective piezoelectric transduction structures 79 on the transduction cavities 75.

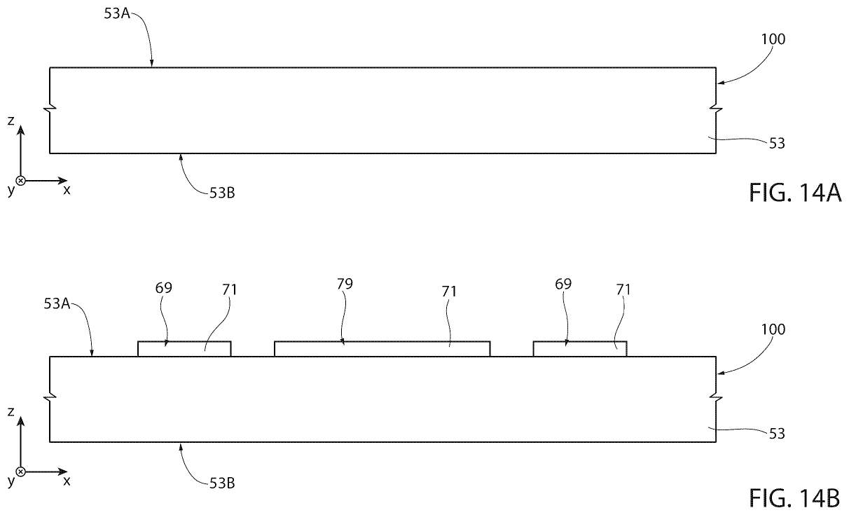

FIGS. 14A-14D show steps of the manufacturing process of the MUT device 50 of FIG. 5.

Initially, FIG. 14A, a wafer 100 of semiconductor material, for example monocrystalline silicon, is arranged which forms the semiconductor body 53.

The piezoelectric elements 71 of the piezoelectric structures 69 and 79 are formed, on the first main face 53A of the semiconductor body 53, FIG. 14B, in a per se known manner. In particular, the piezoelectric elements 71 are arranged side by side to each other along the X axis. For example, and in a manner not shown in detail in FIG. 14B, the formation of the piezoelectric elements 71 occurs similarly to what has been previously described with reference to FIG. 13C.

Then, FIG. 14C, the modulation cavity 65 is formed performing a first deep etch of the silicon from the back, at the second main face 53B of the semiconductor body 53.

In particular, the second dielectric layer previously formed is processed, through known oxide patterning techniques, to provide a first mask 107 of oxide having an opening that exposes the region of the semiconductor body 53 to be removed to form the modulation cavity 65. In detail, this region is aligned along the Z axis with the piezoelectric structures 69 and 79. The first deep etch (e.g., anisotropic chemical etch) of the semiconductor body 53 is performed, by using the first mask 107, so as to form the modulation cavity 65 having a depth along the Z axis such as to define the modulation membrane body 68 having the first thickness S₁.

Then, FIG. 14D, the transduction cavity 75 is formed by performing a second deep etch of the silicon from the back, at the first bottom surface 65A.

In particular, a third dielectric layer is formed on the first bottom surface 65A of the semiconductor body 53, similarly to what has been described for the second dielectric layer. The third dielectric layer provides a second mask 109 of oxide having an opening that exposes the region of the semiconductor body 53 to be removed to form the transduction cavity 75. In detail, this region is aligned along the Z axis with the piezoelectric transduction structure 79. The second deep etch (e.g., anisotropic chemical etch) of the semiconductor body 53 is performed, by using the second mask 109, so as to form the transduction cavity 75 in depth along the Z axis such as to define the transduction membrane body 78 having the second thickness S₂.

After carrying out the final manufacturing steps, including opening the contacts and dicing the wafer 100, the MUT device 50 of FIG. 5 is obtained.

Similarly, the MUT device 50 of FIG. 7 may also be obtained, in particular by forming multiple piezoelectric transduction structures 79 arranged side by side to each other along the X axis and forming respective transduction cavities 75 aligned along the Z axis with the piezoelectric transduction structures 79.

From an examination of the characteristics of the disclosure made according to the present disclosure, the advantages that it affords are evident.

In particular, the MUT device 50 generates acoustic waves whose frequency is modulable, allowing a better correspondence of the generated acoustic waves with the properties of the propagation means and of the object to be detected and thus ensuring better performances of the MUT device 50 in a greater range of applications.

Furthermore, it has been verified that the MUT device 50 allows generating wavefronts (e.g., of the first or the second acoustic waves 80a and 80b) with a frequency fₒ which depends on the emission direction of the acoustic waves. In other words, the frequency fₒ is a function of the tilting angle θ considered between the emission direction of the acoustic waves and the reference direction orthogonal to the first main face 53A of the semiconductor body 53 (e.g., the central axis 77). In particular, the tilting angle θ is defined between the reference direction and an emission direction which is indicative of the position of the object O to be detected relative to the MUT device 50 and which, for example, joins the object O to be detected (exemplarily considered point-like) and the MUT device 50 (in detail, a reference point of the MUT device 50, such as a center of the central portion 67′ of the membrane body 67 in top view).

In particular, by applying the first actuation voltage with a sinusoidal profile to the first actuation frequency, the modulation membrane 73 oscillates at the first vibration frequency (here indicated with the reference fᵣ₁ and equal to the first actuation frequency) and the displacement Zₘ of the modulation membrane 73 along the Z axis is of the sinusoidal type.

In this case, the oscillation speed Vₘ of the modulation membrane 73 is equal to Vₘ (t)=2πfᵣ₁Z₁ sin(2πfᵣ₁t), where Z₁ is the oscillation amplitude of the modulation membrane 73 (i.e., double the maximum value of the displacement of the modulation membrane 73 along the Z axis with respect to its rest position). Furthermore, Vₛ(t,θ)=Vₘ(t)·cos(θ) is the relative speed between the MUT device 50 and the object O to be detected (i.e., between the acoustic source and the observer) and is a function of the tilting angle θ.

Furthermore, the emitted or detected acoustic waves have a frequency (here indicated with the reference fₒ and also hereinafter referred to as acoustic wave frequency) which is equal to:

$${f}_{o} ( t , θ ) = \frac{{f}_{r 2}}{1 - {V}_{s} ( t , θ ) / c}$$

where c is the speed of sound in the fluid wherein the MUT device 50 is immersed (for example in the case of applications in air the speed of sound is about 340 m/s) and fᵣ₂ is the second vibration frequency of the transduction membrane 83 (equal to the second actuation frequency).

In greater detail, the emitted or detected acoustic waves have a frequency difference D_{f}, relative to the second actuation frequency fᵣ₂, which is equal to:

$${D}_{f} ( t , θ ) = {f}_{o} ( t , θ ) - {f}_{r 2} = {f}_{r 2} \cdot ( \frac{1}{1 - \frac{{V}_{s} ( t , θ )}{c}} - 1 ) = \frac{{f}_{r 2}}{\frac{c}{{V}_{s} ( t , θ )} - 1}$$

Furthermore, V_{m,max}=2πfᵣ₁Z₁ is the maximum value of the oscillation speed Vₘ of the modulation membrane 73.

Purely for illustrative and non-limiting purposes, the following example embodiment of the MUT device 50 are reported. In addition to what has been indicated above, D_{f,max} indicates the maximum value of the frequency difference D_{f} and D_{f,min} indicates the minimum value of the frequency difference D_{f}, where D_{f,max} and D_{f,min} may be different from each other in absolute value and are defined by the following expressions:

$${D}_{f , max} = \frac{{f}_{r 2}}{\frac{c}{2 π {f}_{r 1} {Z}_{1}} - 1} \\ {D}_{f , min} = - \frac{{f}_{r 2}}{\frac{c}{2 π {f}_{r 1} {Z}_{1}} + 1}$$

According to a first example, fᵣ₁=10 kHz, Z₁=50 μm, fᵣ₂=5 MHz, D_{f,max}=46.6 kHz, D_{f,min}=−45.7 kHz. According to a second example, fᵣ₁=10 kHz, Z₁=50 μm, fᵣ₂=500 kHz, D_{f,max}=4.6 kHz, D_{f,min}=−4.6 kHz. According to a third example, fᵣ₁=25 kHz, Z₁=10 μm, fᵣ₂=500 kHz, D_{f,max}=2.3 kHz, D_{f,min}=−2.3 kHz. According to a fourth example, fᵣ₁=25 kHz, Z₁=50 μm, fᵣ₂=500 kHz, D_{f,max}=11.8 kHz, D_{f,min}=−11.3 kHz. According to a fifth example, fᵣ₁=25 kHz, Z₁=50 μm, fᵣ₂=1 MHz, D_{f,max}=23.6 kHz, D_{f,min}=−22.6 kHz. According to a sixth example, fᵣ₁=5 kHz, Z₁=50 μm, fᵣ₂=1 MHz, D_{f,max}=4.6 kHz, D_{f,min}=−4.6 kHz. Furthermore, the oscillation amplitude Z₂ of the transduction membrane 83 (i.e., double the maximum value of the displacement of the transduction membrane 83 along the Z axis with respect to its rest position) is for example equal to about a few nanometres or tens of nanometres, for example, is equal to about 10 nm.

Since the acoustic wave frequency fₒ depends on the emission direction of the acoustic waves, the MUT device 50 allows performing selective measurements at predetermined tilting angles θ and therefore allows discriminating between multiple objects O present in the field-of-view, FOV, of the MUT device 50. This allows not having necessarily the measurement of the object present in the FOV and closer to the MUT device 50, but rather being capable of discriminating between different emission directions and therefore being capable of measuring the distance even of objects O that are not the closer to the MUT device 50.

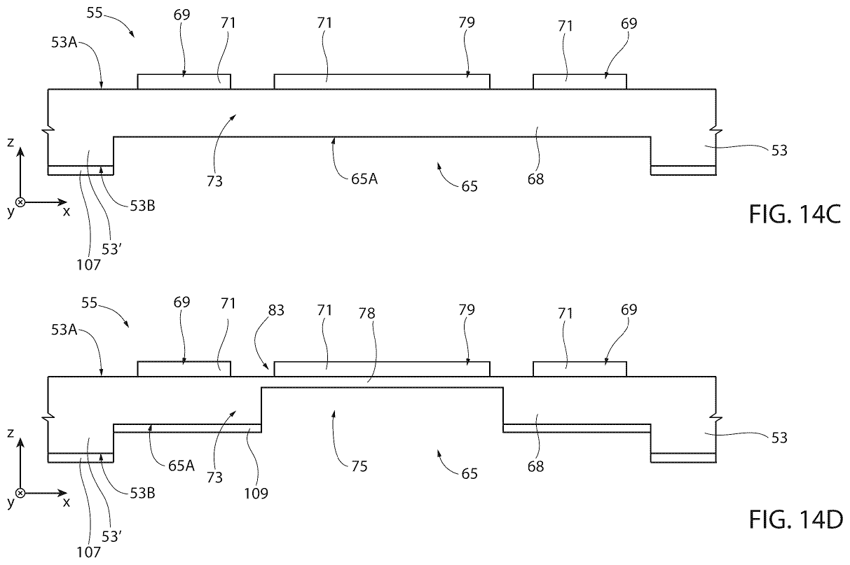

For example, FIG. 15 shows the MUT device 50 with its FOV 96 defined by a first tilting angle range (i.e., defined by θₘᵢₙ≤θ≤θₘₐₓ). A first and a second object O₁ and O₂ are present in the FOV 96 at different tilting angles θ (i.e., they have different emission directions), where the second object O₂ is closer to the MUT device 50 than the first object O₁. By being capable of discriminating the tilting angle θ, the MUT device may also measure the distance of the first object O₁ and not only of the second object O₂. This occurs by generating the emitted waves Wₑ only in a second tilting angle range smaller than the first tilting angle range (emission mode), or by considering only the reflected waves Wᵣ in this second tilting angle range (reception mode).

Finally, it is clear that modifications and variations may be made to the disclosure described and illustrated herein without thereby departing from the scope of the present disclosure, as defined in the attached claims. For example, the different embodiments described may be combined with each other to provide further solutions.

Furthermore, the MUT device 50 may comprise a plurality of MUT elements 55 mutually arranged side by side, for example aligned on rows and columns in top view. For example, and in a manner not shown, each MUT element 55 is connected independently, through electrical connections and contact pads, to a control unit (generally provided in a different die, for example provided as an ASIC, “Application Specific Integrated Circuit”). Alternatively, the MUT elements 55 may be connected to groups, wherein the MUT elements 55 of a group are controlled separately and the groups are controllable separately, to reduce the number and simplify the electrical connections.

A MEMS ultrasonic transducer, MUT, device (50), may be summarized as including a semiconductor body (53) of semiconductor material which defines a support structure (53′), has a first (53A) and a second (53B) main face opposite to each other along a first axis (Z) and integrates at least one MUT element (55) including: a modulation cavity (65) which extends into the semiconductor body (53) from the second main face (53B) towards the first main face (53A); a membrane body (67) of the semiconductor body (53), which extends along the first axis (Z) between the modulation cavity (65) and the first main face (53A) and which is fixed to the support structure (53′) so as to be suspended on the modulation cavity (65), the membrane body (67) including a central portion (67′) and one or more extremal portions (67″) which are interposed, orthogonally to the first axis (Z), between the central portion (67′) and the support structure (53′) and which mutually couple the central portion (67′) and the support structure (53′), the central portion (67′) defining at least one transduction membrane body (78) and the one or more extremal portions (67″) defining a modulation membrane body (68); a piezoelectric modulation structure (69) which extends on the modulation membrane body (68), on the first main face (53A), and forms, with the modulation membrane body (68), a modulation membrane (73) of the MUT element (55), suspended on the modulation cavity (65); at least one transduction cavity (75) which extends into the central portion (67′) of the membrane body (67), the transduction membrane body (78) extending along the first axis (Z) between the transduction cavity (75) and the first main face (53A); and a piezoelectric transduction structure (79) which extends on the transduction membrane body (78), on the first main face (53A), and forms, with the transduction membrane body (78), a transduction membrane (83) of the MUT element (55), suspended on the transduction cavity (75), wherein the modulation membrane body (68) has a first thickness (S₁) along the first axis (Z), and the transduction membrane body (78) has, along the first axis (Z), a second thickness (S₂) smaller than the first thickness (S₁), and wherein the piezoelectric modulation structure (69) is electrically controllable to vibrate the modulation membrane (73) at a first vibration frequency and the piezoelectric transduction structure (79) is configured to generate and/or detect the vibration of the transduction membrane (83) at a second vibration frequency higher than the first vibration frequency, in order to emit and/or receive, by the transduction membrane (83), acoustic waves at a frequency (f 0) which depends on the first vibration frequency and on the second vibration frequency.

The first thickness (S₁) may be a minimum thickness of the modulation membrane body (68) along the first axis (Z) and the second thickness (S₂) may be a maximum thickness of the transduction membrane body (78) along the first axis (Z).

The transduction cavity (75) may be of the buried type or of the exposed type, and may face the modulation cavity (65).

The piezoelectric transduction structure (79) may be superimposed, along the first axis (Z), on the transduction cavity (75) and the piezoelectric modulation structure (69) may be staggered, along the first axis (Z), with respect to the transduction cavity (75), the piezoelectric transduction structure (79) and the piezoelectric modulation structure (69) being arranged side by side to each other orthogonally to the first axis (Z).

The MUT element (55) may have axial symmetry along a central axis (77) parallel to, or coinciding with, the first axis (Z).

The modulation membrane body (68) and the transduction membrane body (78) may be concentric and coaxial along the central axis (77), the modulation membrane body (68) being radially external to the transduction membrane body (78) with respect to the central axis (77).

The central portion (67′) may define a plurality of said transduction membrane bodies (78) arranged side by side to each other orthogonally to the first axis (Z), and the MUT element (55) may include: a respective plurality of said transduction cavities (75) which extend into the central portion (67′) of the membrane body (67), arranged side by side to each other orthogonally to the first axis (Z), each transduction membrane body (78) extending along the first axis (Z) between the respective transduction cavity (75) and the first main face (53A); and a respective plurality of said piezoelectric transduction structures (79) arranged side by side to each other orthogonally to the first axis (Z), each extending on the respective transduction membrane body (78), on the first main face (53A), and forming with the respective transduction membrane body (78) a respective transduction membrane (83) of the MUT element (55), suspended on the respective transduction cavity (75), wherein each transduction membrane body (78) has the second thickness (S₂) along the first axis (Z).

A process of manufacturing a MEMS ultrasonic transducer, MUT, device (50), may be summarized as including the step of forming at least one MUT element (55) in a semiconductor body (53) of semiconductor material, the semiconductor body (53) defining a support structure (53′) and having a first (53A) and a second (53B) main face opposite to each other along a first axis (Z), wherein the step of forming the at least one MUT element (55) includes: forming a modulation cavity (65) in the semiconductor body (53), from the second main face (53B) towards the first main face (53A), thus defining a membrane body (67) of the semiconductor body (53), which extends along the first axis (Z) between the modulation cavity (65) and the first main face (53A) and which is fixed to the support structure (53′) so as to be suspended on the modulation cavity (65), the membrane body (67) including a central portion (67′) and one or more extremal portions (67″) which are interposed, orthogonally to the first axis (Z), between the central portion (67′) and the support structure (53′) and which mutually couple the central portion (67′) and the support structure (53′), the one or more extremal portions (67″) defining a modulation membrane body (68); forming at least one transduction cavity (75) in the central portion (67′) of the membrane body (67), thus defining at least one transduction membrane body (78) of the central portion (67′), the transduction membrane body (78) extending along the first axis (Z) between the transduction cavity (75) and the first main face (53A); forming, on the first main face (53A), a piezoelectric modulation structure (69) on the modulation membrane body (68) and a piezoelectric transduction structure (79) on the transduction membrane body (78), the piezoelectric modulation structure (69) forming with the modulation membrane body (68) a modulation membrane (73) of the MUT element (55), suspended on the modulation cavity (65) and the piezoelectric transduction structure (79) forming with the transduction membrane body (78) a transduction membrane (83) of the MUT element (55), suspended on the transduction cavity (75), wherein the modulation membrane body (68) has a first thickness (S₁) along the first axis (Z) and the transduction membrane body (78) has a second thickness (S₂) smaller than the first thickness (S₁) along the first axis (Z), and wherein the piezoelectric modulation structure (69) is electrically controllable to vibrate the modulation membrane (73) at a first vibration frequency and the piezoelectric transduction structure (79) is configured to generate and/or detect the vibration of the transduction membrane (83) at a second vibration frequency higher than the first vibration frequency, in order to emit and/or receive, by the transduction membrane (83), acoustic waves at a frequency (f 0) which depends on the first vibration frequency and the second vibration frequency.

The step of forming the transduction cavity (75) may include: forming, in a substrate (100) of semiconductor material, a plurality of trenches (102) mutually separated by pillar structures (103); performing an epitaxial growth in a reducing environment so as to form a first superficial layer of semiconductor material, closing the trenches (102) upwardly; and carrying out an annealing such as to cause a migration of atoms of semiconductor material of the pillar structures (103), thus forming the transduction cavity (75) of the buried type and the transduction membrane body (78) closing the transduction cavity (75) upwardly.

The step of forming the piezoelectric modulation structure (69) and the piezoelectric transduction structure (79) may be performed after forming the transduction cavity (75), and the step of forming the modulation cavity (65) may be performed after forming the piezoelectric modulation structure (69) and the piezoelectric transduction structure (79), and may include performing a first deep etch of the silicon from the second main face (53B) of the semiconductor body (53).

The step of forming the modulation cavity (65) may be performed after forming the piezoelectric modulation structure (69) and the piezoelectric transduction structure (79) on the first main face (53A) of the semiconductor body (53) and may include performing a first deep etch of the silicon from the second main face (53B) of the semiconductor body (53), at a first region of the semiconductor body (53) aligned, along the first axis (Z), with the piezoelectric modulation structure (69) and the piezoelectric transduction structure (79), the modulation cavity (65) being delimited upwardly by a first bottom surface (65A) of the semiconductor body (53), and the step of forming the transduction cavity (79) may be performed after forming the modulation cavity (65) and may include performing a second deep etch of the silicon from the first bottom surface (65A) of the semiconductor body (53), at a second region of the semiconductor body (53) aligned, along the first axis (Z), with the piezoelectric transduction structure (79).

A method of controlling a MEMS ultrasonic transducer, MUT, device (50), the control method may be summarized as including the steps of: electrically controlling the piezoelectric modulation structure (69) to vibrate the modulation membrane (73) at the first vibration frequency; and in an emission mode of the MUT device (50), electrically controlling the piezoelectric transduction structure (79) so as to vibrate the transduction membrane (83) at the second vibration frequency to generate said acoustic waves or, in a reception mode of the MUT device (50), detecting, through the piezoelectric transduction structure (79), the vibration of the transduction membrane (83) at the second vibration frequency, induced by said acoustic waves impinging on the MUT device (50).

The step of electrically controlling the piezoelectric transduction structure (79) in the emission mode of the MUT device (50) and the step of detecting the vibration of the transduction membrane (83) in the reception mode of the MUT device (50) may be performed in one or more time intervals (T*) wherein the modulation membrane (73) moves linearly along the first axis (Z), relative to a rest position thereof.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A MEMS ultrasonic transducer (MUT) device, comprising:
a support structure, has a first and a second main face opposite to each other along a first axis;
at least one MUT element including:
a modulation cavity which extends into the support structure from the second main face towards the first main face;
a membrane body of the support structure, which extends along the first axis between the modulation cavity and the first main face and which is fixed to the support structure, the membrane body comprising a central portion and one or more extremal portions which are interposed, orthogonally to the first axis, between the central portion and the support structure and which mutually couple the central portion and the support structure, the central portion defining at least one transduction membrane body and the one or more extremal portions defining a modulation membrane body;
a modulation membrane of the MUT element, suspended on the modulation cavity;
at least one transduction cavity which extends into the central portion of the membrane body, the transduction membrane body extending along the first axis between the transduction cavity and the first main face; and
a transduction membrane of the MUT element, suspended on the transduction cavity,
wherein the modulation membrane body has a first thickness along the first axis, and the transduction membrane body has, along the first axis, a second thickness smaller than the first thickness.

2. The device of claim 1 wherein the modulation membrane includes a piezoelectric modulation structure which extends on the modulation membrane body, on the first main face.

3. The device of claim 2 wherein the transduction membrane includes a piezoelectric transduction structure which extends on the transduction membrane body, on the first main face.

4. The device of claim 3 wherein the piezoelectric modulation structure is electrically controllable to vibrate the modulation membrane at a first vibration frequency and the piezoelectric transduction structure is configured to generate or detect the vibration of the transduction membrane at a second vibration frequency higher than the first vibration frequency, in order to emit and/or receive, by the transduction membrane, acoustic waves at a frequency which depends on the first vibration frequency and on the second vibration frequency.

5. The device of claim 1 wherein the first thickness is a minimum thickness of the modulation membrane body along the first axis and the second thickness is a maximum thickness of the transduction membrane body along the first axis.

6. The device of claim 5 wherein the piezoelectric transduction structure is superimposed, along the first axis, on the transduction cavity and the piezoelectric modulation structure is staggered, along the first axis, with respect to the transduction cavity, the piezoelectric transduction structure and the piezoelectric modulation structure being arranged side by side to each other orthogonally to the first axis.

7. The device according to claim 6 wherein the modulation membrane body and the transduction membrane body are concentric and coaxial along the central axis, the modulation membrane body being radially external to the transduction membrane body with respect to the central axis.

8. The device according to claim 7 wherein the central portion defines a plurality of said transduction membrane bodies arranged side by side to each other orthogonally to the first axis, and
wherein the MUT element comprises:
a respective plurality of said transduction cavities which extend into the central portion of the membrane body, arranged side by side to each other orthogonally to the first axis, each transduction membrane body extending along the first axis between the respective transduction cavity and the first main face; and
a respective plurality of said piezoelectric transduction structures arranged side by side to each other orthogonally to the first axis, each extending on the respective transduction membrane body, on the first main face, and forming with the respective transduction membrane body a respective transduction membrane of the MUT element, suspended on the respective transduction cavity,
wherein each transduction membrane body has the second thickness along the first axis.

9. A process of manufacturing a MEMS ultrasonic transducer (MUT) device, comprising:
forming at least one MUT element in a semiconductor body of semiconductor material, the semiconductor body defining a support structure and having a first and a second main face opposite to each other along a first axis,
wherein forming the at least one MUT element comprises:
forming a modulation cavity in the semiconductor body, from the second main face towards the first main face, thus defining a membrane body of the semiconductor body, which extends along the first axis between the modulation cavity and the first main face and which is fixed to the support structure so as to be suspended on the modulation cavity, the membrane body comprising a central portion and one or more extremal portions which are interposed, orthogonally to the first axis, between the central portion and the support structure and which mutually couple the central portion and the support structure, the one or more extremal portions defining a modulation membrane body;
forming at least one transduction cavity in the central portion of the membrane body, thus defining at least one transduction membrane body of the central portion, the transduction membrane body extending along the first axis between the transduction cavity and the first main face;
forming, on the first main face, a piezoelectric modulation structure on the modulation membrane body and a piezoelectric transduction structure on the transduction membrane body, the piezoelectric modulation structure forming with the modulation membrane body a modulation membrane of the MUT element, suspended on the modulation cavity and the piezoelectric transduction structure forming with the transduction membrane body a transduction membrane of the MUT element, suspended on the transduction cavity,
wherein the modulation membrane body has a first thickness along the first axis and the transduction membrane body has a second thickness smaller than the first thickness along the first axis,
wherein the piezoelectric modulation structure is electrically controllable to vibrate the modulation membrane at a first vibration frequency and the piezoelectric transduction structure is configured to generate and/or detect the vibration of the transduction membrane at a second vibration frequency higher than the first vibration frequency, in order to emit and/or receive, by the transduction membrane, acoustic waves at a frequency which depends on the first vibration frequency and the second vibration frequency.

10. The manufacturing process according to claim 9 wherein of forming the transduction cavity comprises:
forming, in a substrate of semiconductor material, a plurality of trenches mutually separated by pillar structures;
performing an epitaxial growth in a reducing environment so as to form a first superficial layer of semiconductor material, closing the trenches upwardly; and
carrying out an annealing such as to cause a migration of atoms of semiconductor material of the pillar structures, thus forming the transduction cavity of the buried type and the transduction membrane body closing the transduction cavity upwardly.

11. The manufacturing process according to claim 10 wherein of forming the piezoelectric modulation structure and the piezoelectric transduction structure is performed after forming the transduction cavity, and
wherein of forming the modulation cavity is performed after forming the piezoelectric modulation structure and the piezoelectric transduction structure and comprises performing a first deep etch of the silicon from the second main face of the semiconductor body.

12. The manufacturing process according to claim 9 wherein of forming the modulation cavity is performed after forming the piezoelectric modulation structure and the piezoelectric transduction structure on the first main face of the semiconductor body and comprises performing a first deep etch of the silicon from the second main face of the semiconductor body, at a first region of the semiconductor body aligned, along the first axis, with the piezoelectric modulation structure and the piezoelectric transduction structure, the modulation cavity being delimited upwardly by a first bottom surface of the semiconductor body, and
wherein of forming the transduction cavity is performed after forming the modulation cavity and comprises performing a second deep etch of the silicon from the first bottom surface of the semiconductor body, at a second region of the semiconductor body aligned, along the first axis, with the piezoelectric transduction structure.

13. A method, comprising:
controlling a MEMS ultrasonic transducer (MUT) device, the controlling including:
vibrating a modulation membrane at a first vibration frequency by electrically controlling a piezoelectric modulation structure; and
vibrating a transduction membrane at a second vibration frequency in an emission mode of the MUT device, electrically controlling the piezoelectric transduction structure;
detecting in a reception mode of the MUT device through the piezoelectric transduction structure, a vibration of the transduction membrane at the second vibration frequency, induced by acoustic waves impinging on the MUT device.

14. The method according to claim 13 wherein the electrically controlling the piezoelectric transduction structure in the emission mode of the MUT device and the detecting the vibration of the transduction membrane in the reception mode of the MUT device in one or more time intervals wherein the modulation membrane moves linearly along the first axis, relative to a rest position.

15. The method of claim 14 wherein the MUT device includes a support structure, has a first and a second main face opposite to each other along a first axis and at least one MUT element that includes:
a modulation cavity which extends into the support structure from the second main face towards the first main face;
a membrane body of the support structure.

16. The method of claim 15 wherein the membrane body extends along the first axis between the modulation cavity and the first main face and which is fixed to the support structure, the membrane body comprising a central portion and one or more extremal portions which are interposed, orthogonally to the first axis, between the central portion and the support structure and which mutually couple the central portion and the support structure, the central portion defining at least one transduction membrane body and the one or more extremal portions defining a modulation membrane body.

17. The method of claim 16 wherein the MUT element includes:
a modulation membrane of the MUT element, suspended on the modulation cavity;
at least one transduction cavity which extends into the central portion of the membrane body, the transduction membrane body extending along the first axis between the transduction cavity and the first main face; and
a transduction membrane of the MUT element, suspended on the transduction cavity.

18. The method of claim 17 wherein the MUT element includes the modulation membrane body has a first thickness along the first axis, and the transduction membrane body has, along the first axis, a second thickness smaller than the first thickness.
